(19) United States
(12) Patent Application Publication
(10) Pub. No.: US 2008/0135838 A1
(43) Pub. Date: Jun. 12, 2008

(54) THIN FILM TRANSISTOR, METHOD OF FABRICATING THE SAME, AND ORGANIC LIGHT EMITTING DIODE DISPLAY DEVICE INCLUDING THE SAME

(75) Inventors: HYE-HYANG PARK, Suwon-si (KR); Byoung-Deog Choi, Suwon-si (KR)

Correspondence Address: STEIN, MCEWEN & BUI, LLP, 1400 EYE STREET, NW, SUITE 300, WASHINGTON, DC, 20005, US

(73) Assignee: Samsung SDI Co., Ltd, Suwon-si (KR)

(21) Appl. No.: 11/951,525

(22) Filed: Dec. 6, 2007

(30) Foreign Application Priority Data
Dec. 6, 2006 (KR) 2006-123044

(51) Int. Cl. H01L 29/786; H01L 33/00; H01L 21/04

(52) U.S. Cl. 257/40; 257/347; 257/52; 438/166; 257/E51.018; 257/E29.273; 257/E21.04

(57) ABSTRACT

Provided are a thin film transistor, a method of fabricating the thin film transistor, and an organic light emitting diode display device (OLED display device) including the thin film transistor having improved characteristics of the thin film transistor. The thin film transistor includes: a substrate; a semiconductor layer disposed on the substrate; a gate insulating layer disposed on the semiconductor layer, and formed of a thermal oxide layer patterned to correspond to the semiconductor layer; a gate electrode disposed on the gate insulating layer, and disposed to correspond to a predetermined region of the semiconductor layer; an interlayer insulating layer disposed on an entire surface of the substrate; and source and drain electrodes electrically connected to the semiconductor layer.

### CROSS-REFERENCE TO RELATED APPLICATION

This application claims the benefit of Korean Application No. 2006-123044, filed Dec. 6, 2006, the disclosure of which is incorporated herein by reference.

### BACKGROUND OF THE INVENTION

1. Field of the Invention

Aspects of the present invention relate to a thin film transistor, a method of fabricating the thin film transistor, and an organic light emitting diode display device (OLED display device) including the thin film transistor. More particularly, aspects of the present invention relate to a thin film transistor, a method of fabricating the thin film transistor, and an OLED display device including the thin film transistor, so as to have a crystallized polysilicon layer with good crystallinity, a substrate having been prevented from being bent due to a high crystallization temperature during crystallization, and improved characteristics by use of a thermal oxide layer formed during the crystallization as a gate insulating layer.

2. Description of the Related Art

In a general method of fabricating a thin film transistor used in a display device, amorphous silicon is deposited on a transparent substrate formed of glass or quartz, is dehydrogenated, is ion implanted with impurities to form a channel, and is crystallized, to thereby form a semiconductor layer. Subsequently, a gate insulating layer is formed on the semiconductor layer, and a gate electrode, an interlayer insulating layer, and source and drain electrodes are formed thereon, to thereby form the thin film transistor.

Within the above described process, methods of crystallizing the amorphous silicon into a polysilicon are classified as a low temperature crystallization method and a high temperature crystallization method. The low temperature crystallization method mainly uses an excimer laser annealing method, which is performed using a crystallization temperature of about 450° C. While the excimer laser annealing method may use a glass substrate which is relatively inexpensive, the used excimer laser device is expensive and its optimal size is limited, to thereby increase the entire manufacturing cost of the thin film transistor.

On the other hand, the high temperature crystallization method includes a solid phase crystallization method, a rapid thermal annealing (RTA) method, or the like. However, since the solid phase crystallization method should heat the amorphous silicon to a temperature of 600° C. or more for 20 hours or more, a polysilicon that is crystallized from the amorphous silicon contains numerous crystalline defects to make it difficult to obtain sufficient field-effect mobility. In addition, a substrate subjected to the solid phase crystallization method is likely to be deformed during a subsequent annealing process. However, if the crystallization temperature is decreased, productivity may be decreased.

Meanwhile, the RTA method may complete the crystallization of the amorphous silicon within a relatively short time. However, a substrate is also likely to be deformed due to an abrupt thermal shock that may occur during the method, and the crystallized polysilicon may have bad electrical characteristics.

In addition, the general method of fabricating the thin film transistor includes forming a gate insulating layer for insulating the semiconductor layer that is formed of a silicon oxide layer or a silicon nitride layer using a chemical vapor deposition (CVD) method. However, in this case, since quality and uniformity of the gate insulating layer may be degraded subsequently, the gate insulating layer should be deposited to a thickness of 1000 Å or more.

In view of the above, it is difficult to adjust the various electrical characteristics of the thin film transistor, and characteristics of the thin film transistor may be deteriorated thereby.

### SUMMARY OF THE INVENTION

Aspects of the present invention provides a thin film transistor, a method of fabricating the thin film transistor, and an organic light emitting diode display device (OLED display device) including the thin film transistor having a crystallized polysilicon layer with good crystallinity, a substrate having been prevented from being bent due to a high crystallization temperature during crystallization, and improved characteristics by use of a thermal oxide layer formed during the crystallization as a gate insulating layer.

According to an aspect of the present invention, a thin film transistor includes: a substrate; a semiconductor layer disposed on the substrate; a gate insulating layer disposed on the semiconductor layer, and formed of a thermal oxide layer patterned to correspond to the semiconductor layer; a gate electrode disposed on the gate insulating layer, and disposed to correspond to a predetermined region of the semiconductor layer; an interlayer insulating layer disposed on an entire surface of the substrate; and source and drain electrodes electrically connected to the semiconductor layer.

According to another aspect of the present invention, a method of fabricating a thin film transistor includes: providing a substrate; forming an amorphous silicon layer on the substrate; annealing the amorphous silicon layer in an H₂O atmosphere to simultaneously form a polysilicon layer and a thermal oxide layer disposed on the polysilicon layer; patterning the polysilicon layer and the thermal oxide layer to respectively form a semiconductor layer and a gate insulating layer; forming a gate electrode to correspond to a predetermined region of the semiconductor layer; and forming an interlayer insulating layer on an entire surface of the substrate and electrically connecting source and drain electrodes to the semiconductor layer.

According to another aspect of the present invention, an OLED display device includes: a substrate; a semiconductor layer disposed on the substrate; a gate insulating layer disposed on the semiconductor layer, and formed of a thermal oxide layer patterned to correspond to the semiconductor layer; a gate electrode disposed on the gate insulating layer, and disposed to correspond to a predetermined region of the semiconductor layer; an interlayer insulating layer disposed on an entire surface of the substrate; source and drain electrodes electrically connected to the semiconductor layer; a first electrode electrically connected to the source or drain electrode; and an organic layer and a second electrode disposed on the first electrode.

According to another aspect of the present invention, a thin film transistor includes: a substrate; a semiconductor layer disposed on the substrate and comprising polysilicon formed from an amorphous silicon layer; a thermal oxide layer formed on the semiconductor layer and formed from the amorphous silicon layer to function as a gate insulating layer; a gate electrode disposed directly on the thermal oxide layer; an interlayer insulating layer disposed over the substrate; and source and drain electrodes electrically connected to the semiconductor layer.

According to another aspect of the present invention a method of forming a thin film transistor includes: providing a substrate; forming a semiconductor layer on the substrate that includes polysilicon formed from an amorphous silicon layer; forming a thermal oxide layer on the semiconductor layer from the amorphous silicon layer to function as a gate insulating layer; forming a gate electrode directly on the thermal oxide layer; forming an interlayer insulating layer over the substrate; and forming source and drain electrodes to be electrically connected to the semiconductor layer.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the aspects, taken in conjunction with the accompanying drawings of which:

FIGS. 1A to 1E are cross-sectional views showing a process of fabricating a thin film transistor in accordance with an aspect of the present invention; and

FIG. 1F is a cross-sectional view of an organic light emitting diode display device (OLED display device) in accordance with an aspect of the present invention.

### DETAILED DESCRIPTION OF THE EMBODIMENTS

Reference will now be made in detail to aspects of the present invention, examples of which are illustrated in the accompanying drawings, wherein like reference numerals refer to the like elements throughout. The aspects are described below in order to explain the present invention by referring to the figures.

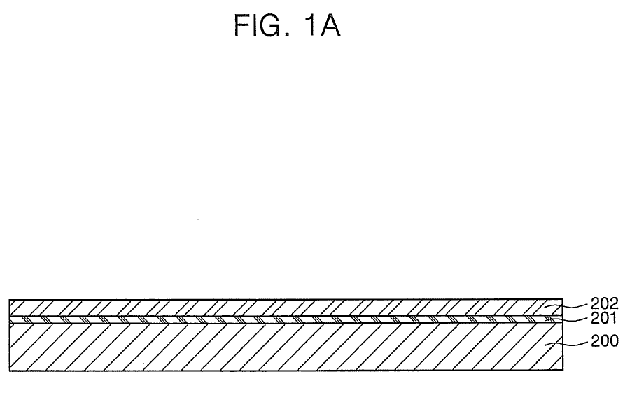

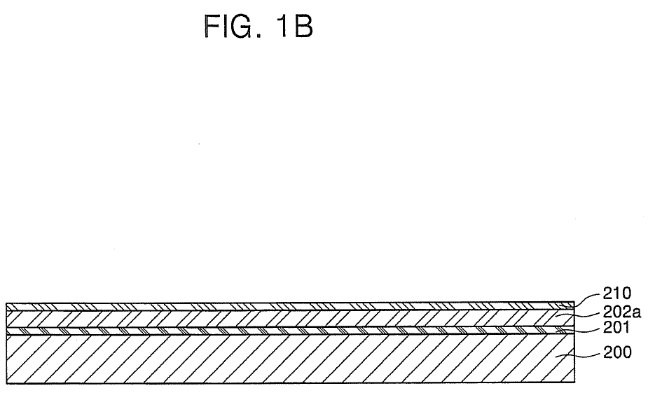

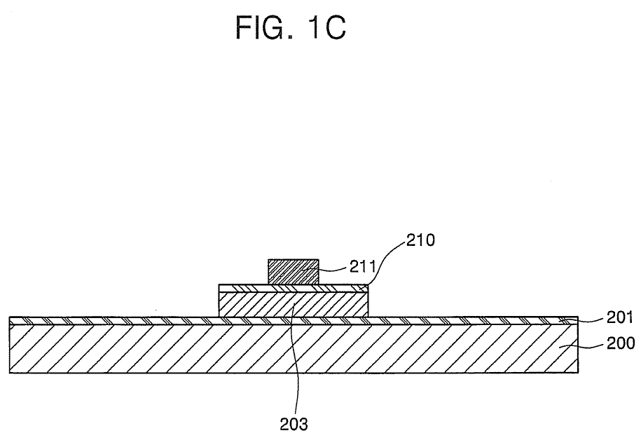

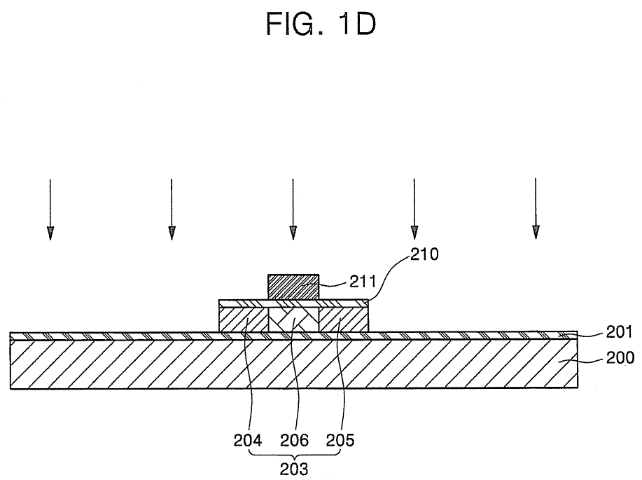

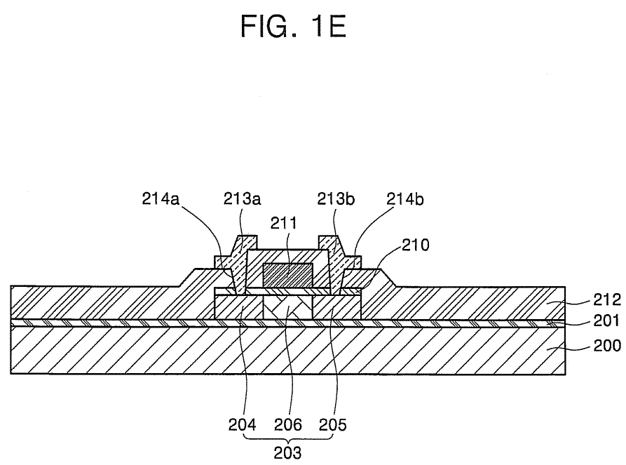

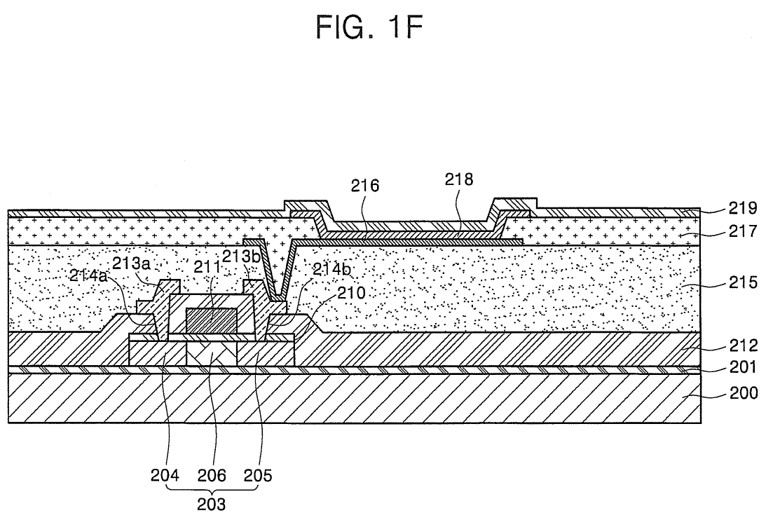

In the various aspects, the thickness of layers and regions may be exaggerated for clarity. FIGS. 1A to 1E are cross-sectional views showing a process of fabricating a thin film transistor in accordance with an aspect of the present invention. Referring to FIG. 1A, a buffer layer 201 is formed on a transparent substrate 200 such as an insulating glass or a plastic substrate. The buffer layer 201 functions to prevent or reduce diffusion of moisture or impurities that are introduced from the underlying substrate 200, or to adjust a transfer rate of heat during crystallization so that a polysilicon layer (not shown) to be formed during the process can be readily crystallized. The buffer layer 201 may be formed of a silicon oxide layer, a silicon nitride layer, or a multi-layer thereof.

Then, an amorphous silicon layer 202 is formed on the buffer layer 201. The amorphous silicon layer 202 may be deposited using a plasma enhanced chemical vapor deposition (PECVD) method, a low pressure chemical vapor deposition (LPCVD) method, or the like. The PECVD method is performed at a temperature of 330° C.-430° C. and a pressure of 1-1.5 Torr using SiH₄+Ar and/or H₂. In addition, the LPCVD method is performed at a temperature of 400° C.-500° C. and a pressure of 0.2-0.4 Torr using Si₂H₆+Ar. Next, as shown in FIG. 1B, the substrate 200 having the buffer layer 201 and the amorphous silicon layer 202 is annealed to crystallize the amorphous silicon layer 202 to form a polysilicon layer 202a, and at the same time, form a thermal oxide layer 210 on the polysilicon layer 202a. In other aspects, the respective temperature ranges, the pressure ranges, and the gases used in the PECVD and the LPCVD methods may be other than those listed above.

In aspects of the present invention, an annealing process such as a rapid thermal annealing (RTA) method or equipment such as a furnace are used to perform a typical high temperature annealing process. Nevertheless, while the typical high temperature annealing process performs the annealing process in an inactive atmosphere of N₂ or O₂, aspects of the present invention performs the annealing process in an atmosphere of H₂O. In aspects of the present invention, when the annealing process is performed in the atmosphere of H₂O, it is possible to reduce an annealing time for the same temperature, or lower the annealing temperature for the same time as compared to that of performing the annealing process in the atmosphere of N₂ or O₂.

In particular, if a typical transparent insulating substrate formed of glass is used, the substrate may be bent at a high temperature. However, in aspects of the present invention, a substrate may be prevented from being bent by decreasing the annealing temperature of the substrate and the formed layers.

The annealing temperature according to aspects of the present invention may be within a range of 550° C.-750° C., and preferably 600° C.-710° C., though not required. Considering that amorphous silicon is crystallized at an appropriate temperature, the annealing temperature may be 550° C. or more, though not required, and considering that the substrate is deformed at a high temperature, the annealing temperature may be 750° C. or less, though not required. In addition, within the temperature of 600° C.-710° C., it is possible to obtain good polysilicon characteristics for an appropriate annealing time.

Further, a pressure of H₂O may be within a range of 10,000-2 MPa, though not required Considering that the annealing time is determined by a relationship in which a crystallization speed of the amorphous silicon is in proportion to the pressure, the pressure of the H₂O may be 10,000 Pa or more, though not required, and considering that there is a probability of explosion due to a high pressure, the pressure of the H₂O may be 2 MPa or less, though not required.

Accordingly, when the annealing process is performed in the H₂O atmosphere, while the amorphous silicon layer 202 is crystallized into a polysilicon layer 202a, a thermal oxide layer 210 may be formed on the polysilicon layer 202a, for example, at a location where the H₂O molecules contact the amorphous silicon layer 202 or the polysilicon layer 202a. Accordingly, the growth of the thermal oxide layer 210 proceeds by diffusion of the H₂O into the amorphous silicon layer 202 or the polysilicon layer 202a, and has a growth rate depending on various factors, such as thickness of the growing thermal oxide layer 210, the annealing temperature, the pressure of the H₂O atmosphere, and others.

In various aspects, thermal oxide layer 210 may be formed to a thickness of 50 Å-300 Å. Considering that the thermal oxide layer 210 acts as a gate insulating layer, the thickness of the thermal oxide layer 210 may be 50 Å or more, and considering the manufacturing process time of the thermal oxide layer 210, the thickness of the thermal oxide layer 210 may be 300 Å or less. In addition, the thickness of the thermal oxide layer 210 can be adjusted depending on the annealing temperature and the process time.

Referring to FIG. 1C, the polysilicon silicon layer 202a and the thermal oxide layer 210 are patterned respectively to form a semiconductor layer 203 and a gate insulating layer.

In a typical thin film transistor using a deposited gate insulating layer of a silicon oxide layer or a nitride layer that is formed by a CVD method, the gate insulating layer should be formed to a thickness 1000 Å or more in order to obtain good layer quality and uniformity. However, in aspects of the present invention, the layer thickness of the gate insulating layer can be reduced to 300 Å or less due to the thermal oxide layer 210 (that is formed directly from the amorphous silicon layer 202) so that characteristics of the thin film transistor can be readily adjusted, to thereby improve the characteristics of the thin film transistor.

Then, a gate electrode metal layer (not shown) formed of an Al layer, a single Al alloy layer (such as an Al—Nd layer), or a multi-layer (in which an Al alloy layer is deposited on a Cr or mo alloy layer, for example) is formed. Next, the gate electrode metal layer is etched to form a gate electrode 211 in a predetermined region thereof corresponding to the semiconductor layer 203. In other aspects, the gate electrode metal layer may be formed of other metals or materials.

Referring to FIG. 1D, a predetermined amount of conductive impurity ions is injected into portions of the semiconductor layer 203 to form source and drain regions 204 and 205, and/or to form a channel region 206 using the gate electrode 211 as a mask. The impurity ions may use p-type impurities or n-type impurities to form the thin film transistor. The p-type impurities may be selected from a group consisting of B, Al, Ga, and In, though not required, and the n-type impurities may be selected from a group consisting of P, As, and Sb, though not required. In other aspects, other p-type or n-type impurities may be used.

Referring to FIG. 1E, an interlayer insulating layer 212 is formed on the entire surface of the substrate 200 including the gate electrode 211. Next, predetermined regions of the interlayer insulating layer 212 and the thermal oxide layer 210 are etched to form contact holes 214a, 214b. Further, source and drain electrodes 213a and 213b are formed to be electrically connected to the source and drain regions 204 and 205 through the contact holes 214a, 214b, to thereby complete the thin film transistor.

As described above, the thin film transistor in accordance with an aspect the present invention has advantages of having a crystallized polysilicon layer with good crystallinity, a substrate having been prevented from being bent due to a high crystallization temperature during crystallization, and improved characteristics by use of a thermal oxide layer formed during the crystallization as a gate insulating layer.

FIG. 1F is a cross-sectional view of an organic light emitting diode display device (OLED display device) in accordance with an aspect of the present invention. Referring to FIG. 1F, a planarization layer 215 is formed on an entire surface of the substrate 200. The planarization layer 215 may be formed of an organic layer, an inorganic layer, a composite layer thereof, or other materials. The planarization layer 215 formed of an inorganic layer may be formed using a spin-on-glass (SOG), and the planarization layer 215 formed of an organic layer may be formed using an acryl-based resin, a polyimide-based resin, benzocyclobutene (BCB), or other materials.

As shown, the planarization layer 215 is etched to form a via-hole to expose one of the source and drain electrodes 213a and 213b, so that a formed first electrode 216 is connected to the one of the source and drain electrodes 213a and 213b. A portion of the first electrode 216 may be formed to be disposed on the bottom of the formed via-hole to be in contact with the exposed one of the source and drain electrodes 213a and 213b, and to extend onto the planarization layer 215. The first electrode 216 may be formed of indium tin oxide (ITO) or indium zinc oxide (IZO), for example.

A pixel-defining layer 217 is formed on the entire surface of the substrate 200 including (or over) the first electrode 216 to a thickness sufficient to fill the via-hole in the planarization layer 215, in which the first electrode 216 is disposed. The pixel-defining layer 217 may be formed of an organic material or an inorganic material, preferably an organic material, though not required. More preferably, but not required, the pixel-defining layer 217 is formed of one selected from a group consisting of benzocyclobutene (BCB), acryl-based polymer, and polyimide, or other materials. The pixel-defining layer 217 has good flowability to be formed flatly on the entire surface of the substrate 200.

As shown, the pixel-defining layer 217 is etched to form an opening (or a recess) to expose the first electrode 216, and an organic layer 218 to emit light is formed on the first electrode 216 that is exposed through the opening. The organic layer 218 includes at least an emission layer, and may further include at least one selected from a hole injection layer, a hole transport layer, an electron transport layer, and an electron injection layer, or other materials, though not required.

The second electrode 219 is formed on the entire surface of the substrate 200. The second electrode 219 may be a transmissive electrode formed of Mg, Ag, Al, Ca, or an alloy thereof having a low work function, or other materials, though not required. As a result, an OLED display device in accordance with an aspect of the present invention is completed.

In various aspects of the present invention, the thermal oxide layer may be formed on the semiconductor layer and be formed from the amorphous silicon layer to function as a gate insulating layer. Also, the gate electrode may be disposed directly on the thermal oxide layer. Additionally, the thermal oxide layer as the gate insulating layer may be formed only over the semiconductor layer. Finally, the thermal oxide layer may be formed directly on the semiconductor layer.

In the aspects discussed above in relations to FIGS. 1A-1F, it is possible to provide a thin film transistor, a method of fabricating the thin film transistor, and an OLED display device including the thin film transistor having a polysilicon layer with good crystallinity, and providing the thin film transistor to have excellent characteristics.

In the figures, the dimensions of layers and regions may be exaggerated for clarity. It will also be understood that when a layer or element is referred to as being “on” or “over” another layer or substrate, it can be directly on the other layer or substrate, or intervening layers may also be present. Further, it will be understood that when a layer is referred to as being “under” or “below” another layer, it can be directly under, or one or more intervening layers may also be present.

Although a few aspects of the present invention have been shown and described, it would be appreciated by those skilled in the art that changes may be made in the aspects without departing from the principles and spirit of the invention, the scope of which is defined in the claims and their equivalents.

What is claimed is:

1. A thin film transistor comprising:
a substrate;
a semiconductor layer disposed on the substrate;
a gate insulating layer disposed on the semiconductor layer, and formed of a thermal oxide layer patterned to correspond to the semiconductor layer;
a gate electrode disposed on the gate insulating layer, and disposed to correspond to a predetermined region of the semiconductor layer;
an interlayer insulating layer disposed on an entire surface of the substrate; and
source and drain electrodes electrically connected to the semiconductor layer.

2. The thin film transistor according to claim 1, wherein the thermal oxide layer comprises a silicon oxide layer.

3. The thin film transistor according to claim 1, wherein the thermal oxide layer is formed to a thickness of 50 Å-300 Å.

4. The thin film transistor according to claim 1, further comprising a buffer layer formed on the substrate.

5. A method of fabricating a thin film transistor, comprising:
providing a substrate;
forming an amorphous silicon layer on the substrate;
annealing the amorphous silicon layer in an H₂O atmosphere to simultaneously form a polysilicon layer and a thermal oxide layer disposed on the polysilicon layer;
patterning the polysilicon layer and the thermal oxide layer to respectively form a semiconductor layer and a gate insulating layer;
forming a gate electrode to correspond to a predetermined region of the semiconductor layer; and
forming an interlayer insulating layer on an entire surface of the substrate and electrically connecting source and drain electrodes to the semiconductor layer.

6. The method according to claim 5, further comprising forming a buffer layer on the substrate before forming the amorphous silicon layer.

7. The method according to claim 5, wherein the thermal oxide layer comprises a silicon oxide layer.

8. The method according to claim 5, wherein annealing of the amorphous silicon layer is performed using a rapid thermal annealing (RTA) method.

9. The method according to claim 5, wherein annealing of the amorphous silicon layer is performed at a temperature temperatures of 550° C.-750° C.

10. The method according to claim 5, wherein the H₂O atmosphere is performed under a pressure of 10,000 Pa-2 MPa.

11. The method according to claim 5, wherein, after forming of the gate electrode, impurities are injected into the semiconductor layer to form source and drain regions.

12. An organic light emitting display device (OLED) comprising:
a substrate;
a semiconductor layer disposed on the substrate;
a gate insulating layer disposed on the semiconductor layer, and formed of a thermal oxide layer patterned to correspond to the semiconductor layer;
a gate electrode disposed on the gate insulating layer, and disposed to correspond to a predetermined region of the semiconductor layer;
an interlayer insulating layer disposed on an entire surface of the substrate;
source and drain electrodes electrically connected to the semiconductor layer;
a first electrode electrically connected to the source or drain electrode; and
an organic layer and a second electrode disposed on the first electrode.

13. The OLED according to claim 12, wherein the thermal oxide layer comprises a silicon oxide layer.

14. The OLED according to claim 12, wherein the thermal oxide layer is formed to a thickness of 50 Å-300 Å.

15. The OLED according to claim 12, further comprising a buffer layer formed on the substrate.

16. A thin film transistor comprising:
a substrate;
a semiconductor layer disposed on the substrate and comprising polysilicon formed from an amorphous silicon layer;
a thermal oxide layer formed on the semiconductor layer and formed from the amorphous silicon layer to function as a gate insulating layer;
a gate electrode disposed directly on the thermal oxide layer;
an interlayer insulating layer disposed over the substrate; and
source and drain electrodes electrically connected to the semiconductor layer.

17. The thin film transistor of claim 16, wherein the thermal oxide layer as the gate insulating layer is formed only over the semiconductor layer.

18. The thin film transistor of claim 16, wherein the thermal oxide layer is formed directly on the semiconductor layer.

19. A method of forming a thin film transistor comprising:
providing a substrate;
forming a semiconductor layer on the substrate that includes polysilicon formed from an amorphous silicon layer;
forming a thermal oxide layer on the semiconductor layer from the amorphous silicon layer to function as a gate insulating layer;
forming a gate electrode directly on the thermal oxide layer;
forming an interlayer insulating layer over the substrate; and
forming source and drain electrodes to be electrically connected to the semiconductor layer.

20. The method of claim 19, wherein the thermal oxide layer is formed directly on the semiconductor layer.
